(19) United States
(12) Patent Application Publication
(10) Pub. No.: US 2019/0164852 A1
(43) Pub. Date: May 30, 2019

(54) SYSTEM AND METHOD FOR IN-LINE PROCESSING CONTROL

(71) Applicant: Taiwan Semiconductor Manufacturing Co., Ltd., Hsinchu City (TW)

(72) Inventors: Hsiao-Hua PENG, Hsinchu City (TW); Hann-Ru Cheng, Hsinchu City (TW)

(21) Appl. No.: 15/904,105

(22) Filed: Feb. 23, 2018

Related U.S. Application Data
(60) Provisional application No. 62/591,323, filed on Nov. 28, 2017.

(51) Int. Cl. H01L 21/66; H01L 21/67

(52) U.S. Cl. CPC H01L 22/20; H01L 21/67103; H01L 21/67253; H01L 21/67248; H01L 21/67069

(57) ABSTRACT

Disclosed is an in-line processing control method and system. In one embodiment, the n method comprising: conducting a critical dimension (CD) inspection on a first wafer; generating a first CD map of the first wafer; determining a first temperature profile map and a first plasma processing configuration based on the first CD map of the first wafer, wherein the first plasma processing configuration comprises a first temperature profile map, a first etch time and a first plasma processing condition; and configuring a plasma etching process with the first plasma processing configuration for processing the first wafer.

### CROSS-REFERENCE TO RELATED APPLICATION

The present application claims priority to U.S. Provisional Patent Application No. 62/591,323, filed on Nov. 28, 2017, which is incorporated by reference herein in its entirety.

### BACKGROUND

Plasma enhanced processing techniques have gained widespread use in fabrication of devices for various applications, such as semiconductor integrated devices, microelectronic devices, and microelectromechanical device. Although feature sizes in these applications can vary from sub-micrometers to a few nanometers, advanced technologies for in-line processing control are required during fabrication to monitor the within wafer (WiW) and/or batch-to-batch critical dimension (CD) uniformity to provide maximum production yields. For example, in the manufacturing of integrated circuits, patterning techniques such as photolithography, deposition, and etching are used to form various features such as polysilicon lines, devices (e.g., transistors, diodes, and the like), interconnect structures, contact pads, and the like in device dies on a wafer. Ideally, the etch rate (ER) of a set of identical wafers from an etching processing station should be constant and predictable. However, the etch process exhibits process drift and unpredictable shifts in behavior due to effects, such as, for example incoming wafer variability, chamber maintenance activities, chamber conditioning, etc. Because of these process drifts, critical dimensions of the patterned features may not be uniform within a device die and/or a wafer. Thus, inconsistent ER could result in out-of-specification (OOS) etching. Large across-wafer OOS critical dimensions eventually cause large die-to-die performance variations and thus low production yields. Therefore, monitoring of critical dimensions of features and in-line processing control are important for minimizing critical dimension variations in order to maximize the production yield.

Conventionally, in-line processing control utilizes an advanced processing control (APC) method or a dose mapper (DoMa) method. In an APC method, critical dimensions of features on a trial wafer after development using a photolithography process (hereinafter “after-development inspection” or “ADI”) are inspected using techniques such as scanning electron microscopy (SEM). Similarly, the critical dimensions of a feature after an etching process (hereinafter “after-etch inspection” or “AEI”) are inspected using a SEM. Then the average of the measured critical dimension values at multiple test points across the wafer surface is calculated. The AEI-CD average value is compared to a predefined threshold CD window. If this value is out of the predefined window, the trial run is repeated on a next trail wafer with a reconfigured etching process (e.g., pressure and time are changed), wherein the reconfiguration is based on the AEI-CD feedback. One of the major disadvantages of the APC method is that its feedback to the etching process only enforces the average CD value rather than the CD uniformity on the entire wafer surface. On the other hand, a DoMa mapping method acquires a CD map of patterned features on a wafer surface after an etching process. These DoMa AEI-CD maps are then fed back to the photolithography process instead of the etching process, to adjust parameters, such as for instance dose (e.g., a total number of photons, which is a function of wavelength, intensity and time) during exposure to improve the CD uniformity. Compared to the APC, the DoMa method and applications thereof could improve the AEI-CD uniformity, but requires a time-consuming trial run process.

Furthermore, neither of these methods satisfactorily resolves problems in certain situations, such as when there is an intrinsic non-uniformity of etch rate in an etching processing station, or when changes are made to the station (e.g., after preventative maintenance or tool conditioning). Finally, in order to maximize the production yield, state-of-the-art fabrication facilities typically pair a lithography processing station with an etching processing station, which is not economically efficient because one lithography processing station can be only used with one particular etching processing station for a controllable production yield and duplicating station pairs have to be invested for a desired throughput. Therefore, existing methods of achieving CD uniformity across wafer surfaces are not entirely satisfactory.

### BRIEF DESCRIPTION OF THE DRAWINGS

Aspects of the present disclosure are best understood from the following detailed description when read with the accompanying figures. It is noted that various features are not necessarily drawn to scale. In fact, the dimensions and geometries of the various features may be arbitrarily increased or reduced for clarity of illustration.

FIG. 1 illustrates a block diagram of an in-line processing control system integrating an in-line ADI-CD inspection station into a semiconductor manufacturing production line, in accordance with various embodiments of the present disclosure.

FIG. 2A illustrates a cross-sectional overview of a plasma processing system with a plurality of temperature control elements at the back of a wafer stage for in-line processing control, in accordance with various embodiments of the present disclosure.

FIG. 2B illustrates a top view of a wafer stage with a plurality of temperature control elements in a plasma processing system for in-line processing control, in accordance with various embodiments of the present disclosure.

FIG. 3 illustrates a block diagram of a plasma processing system with a plurality of temperature control elements for in-line processing control, in accordance with various embodiments of the present disclosure.

FIG. 4A illustrates a flowchart of an in-line processing control method, in accordance with various embodiments of the present disclosure.

FIG. 4B illustrates a flowchart of an in-line processing control method, in accordance with various embodiments of the present disclosure.

FIG. 5 illustrates exemplary data showing improved critical dimension uniformity using the present method and system, in accordance with various embodiments of the present disclosure.

### DETAILED DESCRIPTION OF EXEMPLARY EMBODIMENTS

The following disclosure describes various exemplary embodiments for implementing different features of the subject matter. Specific examples of components and arrangements are described below to simplify the present disclosure. These are, of course, merely examples and are not intended to be limiting. For example, it will be understood that when an element is referred to as being “connected to” or “coupled to” another element, it may be directly connected to or coupled to the other element, or one or more intervening elements may be present.

The presented disclosure provides various embodiments of an in-line processing control method and system for controlling a critical dimension uniformity across a wafer by compensating a non-uniformity in a patterned mask layer (e.g., a patterned photoresist layer from a photolithography process) during a later process (e.g., an etched layer from a plasma etching process). Specifically, different from the conventional APC or DoMa methods, this present method utilizes a plurality of temperature control elements on a wafer stage and an ADI-CD (after-develop inspection critical dimension) map. The ADI-CD map is provided as a feedforward input to the plurality of temperature control elements so that etching rates can be locally altered on the semiconductor wafer. The non-uniform etching rate provided by the non-uniform temperature on the wafer surface provides a control over a critical dimension uniformity in the etched layer. Accordingly, the above-mentioned issues may be advantageously avoided.

This description of the exemplary embodiments is set to be understood in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

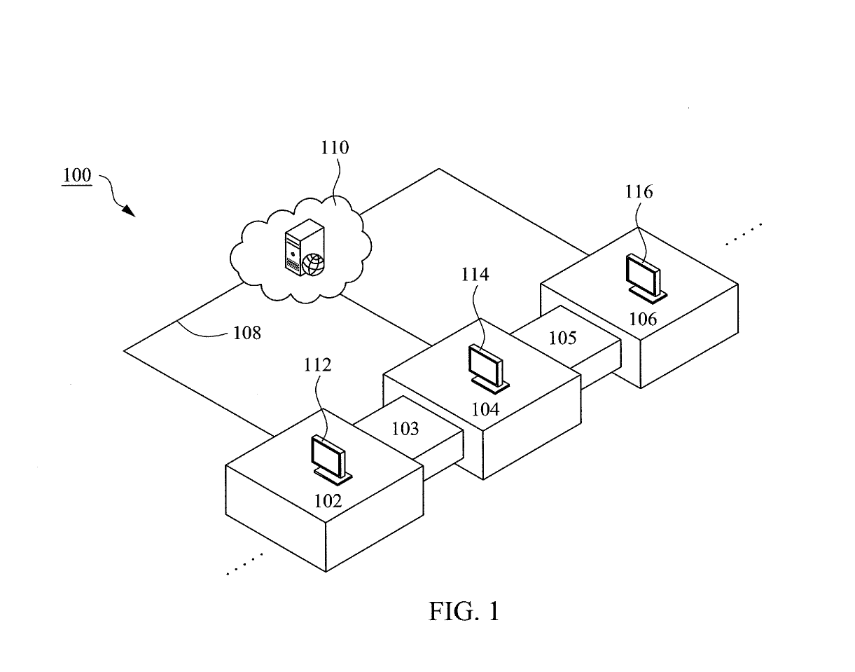

FIG. 1 illustrates a block diagram of an in-line processing control system 100 integrating an in-line ADI-CD inspection station 104 into a semiconductor manufacturing production line, in accordance with various embodiments of the present disclosure. It is noted that the system 100 is merely an example, and is not intended to limit the present disclosure. Accordingly, it is understood that additional operations may be provided before, during, and after the system 100 of FIG. 1, and that some other operations may only be briefly described herein.

The system 100 comprises a plurality of processing stations 102, and 106, and an in-line ADI-CD inspection station 104 located between the processing stations 102 and 106. Examples of IC manufacturing processes conducted in the processing stations 102 and 106 include cleaning, photolithography, wet etching, dry etching, dielectric deposition, metal deposition, and any semiconductor processes known in the art. In some embodiments, the processing station 102 is a photolithography station and the processing station 106 is a plasma processing station. At least one feature can be created in each processing station 102/106 including a photoresist pattern, a metal contact, an etch trench, an isolation, a via structure/hole, an interconnect line, and the like.

At least one in-line ADI-CD inspection station 104 is coupled between the processing stations 102 and 106, in which at least one wafer from the processing station 102 can be inspected for its critical dimensions before being transferred to the next processing station 106. At least one storage station (not shown) can be coupled to the in-line ADI-CD inspection station 104, in which a wafer with out of range critical dimensions, distributions, or defects as determined by the in-line ADI-CD inspection station 104 can be extracted from the production line and stored in the storage station for reprocessing or rejection, instead of being transferred to the next processing station 106.

As discussed in further detail below, in some embodiments, the inspection station 104 can be an after-develop inspection system that provides a measurement of critical dimensions of patterns in a photoresist layer on a wafer after being exposure and developed. The wafer can be a Si wafer with conductive features or a wafer with dielectric layers and interconnects/via structures after the front-end-of-line (FEOL) processes. Typically, the dimension of the photoresist pattern on the wafer surface can be measured by a critical dimension-scanning electron microscope (CD-SEM). The CD-SEM has been widely used to detect small physical defects that are difficult to detect by traditional microscopic optical inspection systems due to their lack of sensitivity and resolution. Besides CD-SEM systems, other types of advanced automated processing control technologies for CD inspection can be used, such as optical critical dimension (OCD) measurement systems using scatterometry with multi-Azimuth angles and multi-channel optics, Normal-Incidence Spectroscopic Polarized Reflectance, and Ellipsometry, in accordance with various embodiments.

The ADI-CD inspection process using a CD-SEM is typically automated, in some embodiments. When the measurement process is started, the CD-SEM will automatically take a wafer out of a cassette, load it to the inspection station, and take microscopic images at a plurality of test positions on the wafer. By counting the number of pixels in a line scan of the microscopic images, a plurality of CD values at the plurality of test positions can be obtained, in accordance with various embodiments.

Referring still to FIG. 1, the microscopic images and/or the plurality of CD values from the in-line ADI-CD inspection station 104 can be stored and preprocessed by a local computer 114. Examples of preprocessing can include reconstruction of the plurality of ADI-CD values and the plurality of test positions into a two-dimensional (2D) ADI-CD map, as described in further detail below. In some embodiments, an image processing operation can be performed by the local computer 114 as part of the preprocessing to automatically compare design criteria with the microscopic images of the wafer surface according to pre-defined threshold values or criterion, e.g., line width, irregular shape, non-uniformity, and the like.

In some embodiments, a wafer that fails to meet a pre-defined threshold value or criterion (e.g., determined to be defective or non-uniformity cannot be fixed by tuning temperature only in a later process), and thus determined to be not qualified for continued processing. Such a wafer is transferred by a conveyor from the in-line ADI-CD inspection station 104 to a cassette in a storage station (not shown) for reprocessing or rejection, in accordance with various embodiments. On the other hand, if the wafer is determined to satisfy the pre-defined threshold value or criterion, then it is transferred by the conveyor to the plasma processing station 106 through the exchange chamber 105 for further processing. In some embodiments, the threshold value may vary depending on the application and can be set by manufacturers. In some embodiments, the processing stations (102 and 106) and in-line ADI-CD inspection station (104) may not located in a same processing bay area and can be coupled by an automatic material handling system (AMHS), wherein wafers/cassettes are moved by an AMHS vehicle on overhead rails or on the ground between stations.

The local computers 112, 114 and 116 are each coupled to a remote computer resource 110 through a connection 108. In some embodiments, the connection 108 may include an Ethernet cable, an optical fiber, a wireless communication media, and/or other networks known in the art. It should be understood that other connections and intermediate circuits can be deployed between the local computers 112, 116 and 114 associated with the processing stations 102, 106 and the in-line ADI-CD inspection station 104, and the remote computer resource 110 to facilitate interconnection.

In some embodiments, the remote computer resource 110 includes a computer network, one or more servers, applications, and/or data centers, generally known as the “cloud” or cloud computing. The ADI-CD map is transferred from the local computer 114 to the remote computer resource 110 through the connection 108. The remote computer resource 110 is configured to determine a plurality of temperature values based on the plurality of CD values in the ADI-CD map and preconfigured plasma processing conditions (e.g., from a user or a recipe), which is then used to construct a temperature profile map, in accordance with various embodiments. The temperature profile map is then transferred to the local computer 116 associated with a plasma processing station 106 through the connection 108. In some embodiments, the remote computer resource 110 may be unnecessary if the local computer 114 can perform analysis of the ADI-CD map locally and provide the temperature profile map directly to the local computer 116 of the plasma processing station 106, for example, via either wired or wireless communication.

Referring still to FIG. 1, the local computer 116, after receiving the temperature profile map and plasma processing conditions from the remote computer resource 110, configures the plasma processing conditions (e.g., pressure, gas, temperature, power, etc.) for the plasma etching, in accordance with various embodiments. As discussed further in detail below, in some embodiments, the local computer 116 provides control signals to a plurality of temperature control elements on the wafer stage within the plasma processing station 106, each of which comprises at least one of a heating element, a cooling element and a sensing elements. The control signal from the local computer 116 is generated based on the temperature profile map received to locally adjust the temperature on the wafer stage, and thus the temperature-dependent etch rate to compensate for the non-uniformity in the ADI-CD map. Thus, a desired CD uniformity on the wafer after the plasma processing can be achieved.

Although the system 100 in the illustrated embodiment of FIG. 1 includes only two processing stations 102/106, one in-line ADI-CD inspection station 104, two exchange chambers 103/105, three local computers 112/114/116, and one remote computer resource 110, it is understood that the embodiment of FIG. 1 is merely provided for illustration purposes. The system 100 may include any desired number of processing stations with any desired number of in-line ADI-CD inspection stations, and storage stations while remaining within the scope of the present disclosure. Furthermore, in some embodiments, an in-line ADI-CD inspection station 104 can be coupled to two or more processing stations 102/106 and/or two or more storage stations. In some embodiments, two or more in-line ADI-CD inspection stations 104 can be located between two processing stations providing complementary inspections using different techniques (e.g., electrical and/or optical measurement).

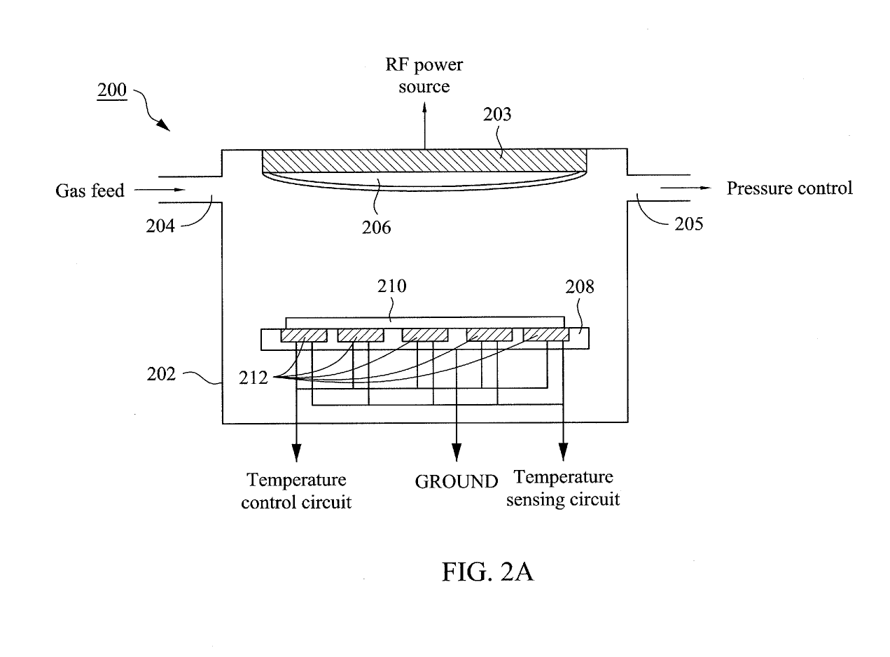

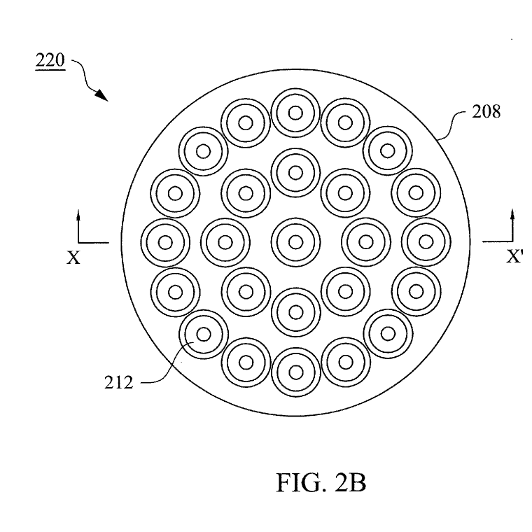

FIG. 2A illustrates a cross-sectional overview of a plasma processing system 200 with a plurality of temperature control elements 212 on a wafer stage 208 for in-line processing control, in accordance with various embodiments of the present disclosure. The processing chamber 202 comprises at least one plasma cathode 203, at least one gas-feeding port 204 connected to at least one gas inputs 204, and at least one vacuum port 205 connected to a pressure control unit (e.g., vacuum pump). In some embodiments, the at least one gas-feeding port 204 can be located in close proximity to the cathode (e.g., behind the cathode). The each of the at least one plasma cathode 203 is coupled to a radio frequency (RF) power source and a respective matching circuit (not shown) operating at frequencies from a few tens of kilohertz (KHz) to tens of megahertz (MHz) at a pressure of a few millitorr (mTorr) to a few Torr. By applying an AC voltage between the plasma cathode 203 and the wafer stage 208, a plasma 206 (i.e., a gas that contains ionized atoms or molecules) can be formed on the plasma cathode 203 and may extend across the space between the plasma cathode 203 and the wafer stage 208 to the surface of a semiconductor wafer 210, in accordance with certain embodiments. In some embodiments, for a plasma deposition processing station, the plasma cathode 203 can be directly connected to a DC discharge power source to form the plasma 206 at a pressure of a few mTorr to a few Torr. In some embodiments, technologies, such as for instance inductively coupled plasma (ICP), electron cyclotron resonance (ECR), microwave, and helicon wave, can be integrated with the RF power source for creation of high-density discharges with desired deposition and/or etching properties.

The plasma processing system 200 can be a plasma etching processing station or a plasma-enhanced deposition processing station (e.g., plasma enhanced chemical vapor deposition (PECVD), plasma enhanced atomic layer deposition (PEALD), etc.), in accordance with various embodiments. According to the exemplary embodiment described herein, the plasma processing system 200 can be used in processing the surface layers of a semiconductor wafer 210. For example, any of a photoresist layer, mask layer, or other layers of a semiconductor wafer as desired, can be processed before or after a plasma processing step, or any combination thereof, according to a specified recipe. The recipe also specifies conditions used to establish the proper environment in the plasma processing chamber 202 for realizing the desired features and feature dimensions on the semiconductor wafer 210. In some embodiments, the recipe can also specify the plasma processing conditions including a type of reactant gas to be introduced into the plasma processing chamber and its flow rate, a pressure during reaction, a power and frequency of the RF signal provided to the plasma cathode 203 or the wafer stage 208.

The back of the wafer stage 208 can be coupled to electrical ground, according to some embodiments. In certain embodiments, the wafer stage 208 can be also coupled to an RF power source. Although not shown in the figure, for the ones with ordinary skill in the art it is understandable that the plasma processing chamber 202 may be also equipped with a plurality of pressure gauges, thickness monitor systems (quartz crystal monitor, spectroscopic ellipsometer, reflection high-energy electron diffraction detector (RHEED)), shutters, a rotational manipulator, viewports, transfer ports, etc.

In some embodiments, the gas through the gas-feeding port 204 to the plasma processing chamber 202 may include at least one or a combination of O₂, Ar, N₂, H₂, NH₃, N₂O, CF₄, SF₆, CCl₄, CH₄, H₂S, SiH₄, metal-containing precursors, etc.

The wafer 210 may be a bulk silicon substrate although other semiconductor materials including group III, group IV, and group V elements may also be used. Alternatively, the substrate may be a silicon-on-insulator (SOI) substrate. In some embodiments, a device layer may be a polysilicon layer disposed on a substrate (not shown) for the formation of one or more polysilicon gates on the wafer 210. In another embodiment, the device layer may be a metallization layer such as an inter-layer dielectric (ILD) or an inter-metal dielectric layer (IMD) for forming interconnect structures (e.g., metal lines and/or vias). In yet other embodiments, the device layer may be any layer in the wafer 210 that may be patterned using photolithography and etching processes. The wafer 210 may include numerous device layers. Furthermore, the device layer may include a buffer layer (e.g., an oxide interfacial layer, not shown), an etch stop layer (e.g., a silicon nitride layer, a silicon carbide layer, or the like), or the like. A hard mask may be formed over the device layer for use as a patterning mask. The hard mask may comprise an oxide, silicon oxynitride (SiON), silicon nitride (Si₃N₄), titanium nitride (TiN), or the like.

Referring still to FIG. 2, the wafer stage 208 in the plasma processing system 200 is equipped with a plurality of temperature control elements 212. The plurality of temperature control elements 212 are assembled on the wafer stage 208, and each are independently controlled by a temperature control circuit and monitored by a temperature sensing circuit, in accordance with certain embodiments. The temperature control/sensing circuit can be located within a processing chamber 202 of the plasma processing system 200 enclosed in a Faraday shield to protect electronic circuits from RF interference or outside the processing chamber 202, in accordance with various embodiments.

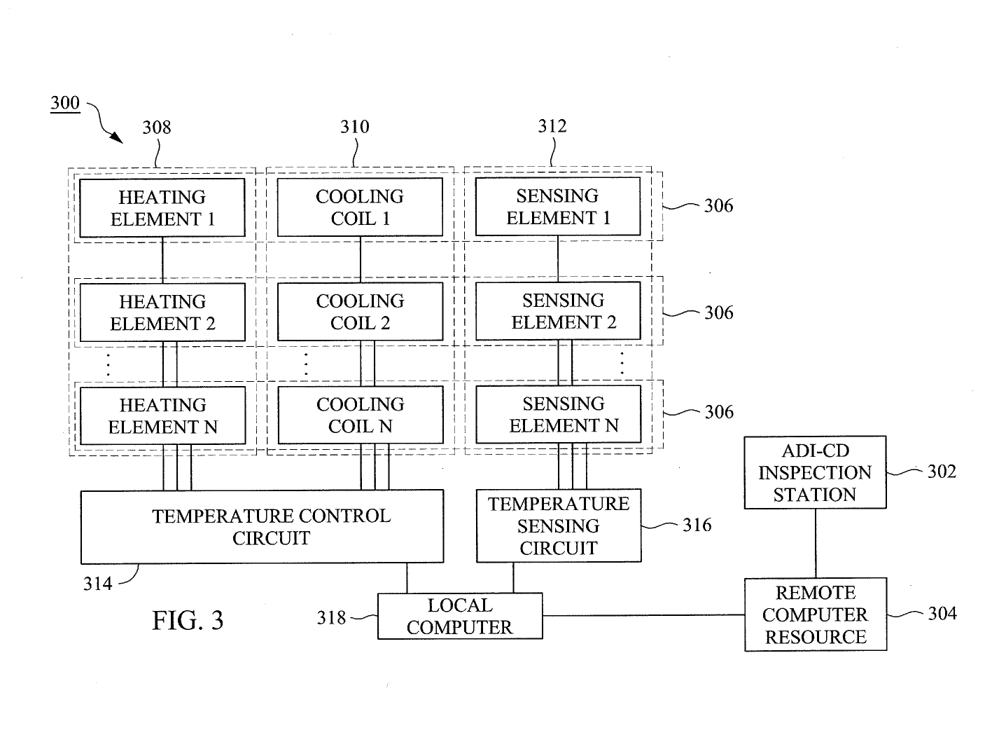

FIG. 2B illustrates a top view 220 of a wafer stage 208 in a plasma processing system 200 equipped with a plurality of temperature control elements 212 for in-line processing control, in accordance with various embodiments. Each of the plurality of temperature control elements 212 includes at least one of: a heating element, a cooling element, and a sensing element, which will be discussed in detail in FIG. 3 below. The plurality of temperature control elements 212 on the wafer stage 208 is operable to create a temperature profile map on the semiconductor wafer 210.

FIG. 3 illustrates a block diagram 300 of a plasma processing system with a plurality of temperature control elements 306 for in-line processing control, in accordance with various embodiments of the present disclosure. A first wafer is scanned by an ADI-CD inspection system 302 and a plurality of critical dimension values at a plurality of test positions on a patterned photoresist layer on the first wafer after a photolithography patterning process is determined by the ADI-CD inspection system. The plurality of critical dimension values at the respective test positions is then assembled to produce a first ADI-CD map of the first wafer. The in-line ADI-CD inspection station 302 can use a CD-SEM and/or other suitable technologies discussed above. The number of test positions may be specified by users and can be a few hundred or more depending on a wafer size and a resolution requirement, in accordance with various embodiments. In some embodiments, the number of test positions is also determined by the arrangement of the plurality of temperature control elements on the wafer stage. Furthermore, the first ADI-CD map of the first wafer can be transmitted to a remote computer resource 304. Meanwhile, the first wafer is then transferred from the in-line ADI-CD inspection station to the plasma processing station.

Tuning the temperature can change the ratio between isotropic etching on all the exposed surfaces by chemical reactions and anisotropic etching on the bottom of the structures by ion bombardment. To control the position-dependent etching rate (e.g., isotropic and anisotropic etching) in both horizontal and vertical directions thus the ability to compensate the non-uniformity in the patterned photoresist layer, different temperature can be applied at different positions. To do this, the remote computer resource 304 then determines a plurality of temperature values based on the plurality of CD values received from the in-line ADI-CD inspection station, which are then assembled to produce a first temperature profile map on the surface of the first wafer. For a non-uniform ADI-CD map, the first temperature profile map is thus not uniform across the surface of the first wafer, in accordance with some embodiments. A non-uniform etch rate caused by the non-uniform first temperature profile map applied to the first wafer is able to compensate the non-uniformity in the patterned photoresist layer, i.e., non-uniformity in the first ADI-CD map. For example, a position that has an ADI-CD value smaller than the average value may require a higher etch rate and thus a higher temperature. Similarly, a position that have an ADI-CD value greater than the average value may require a smaller etch rate thus a lower temperature. Accordingly, a uniformity of CD values on the surface of the first wafer after etching can be realized.

Besides temperature, the etching rate is also a function of chamber pressure and pressure distribution (uniformity). For example at high pressure the etch rate may drop due to the increased scattering collisions of ions traversing the Faraday dark space, thus can increase angular spread in incident ions to the wafer, which cause increase of undercut and thus lateral etch. Other parameters that can affect the etching rate besides temperature and pressure include, gas flow rate, plasma power, cleanness, exposed material for etching, etc. Therefore, a first temperature profile map according to the first ADI-CD map is actually determined based on particular plasma processing conditions, e.g., pressure and its distribution, plasma power and its distribution, flow rate, cleanness of the reaction chamber, temperature history (ramping profile), etc. In some embodiments, the plasma processing conditions are predefined in the plasma processing station or specified by a user in a recipe. The remote computer resource 304 only determines the plurality of temperature values and thus the first temperature profile map which is then transferred to a local computer 318. In some embodiments, the plasma processing conditions are not predefined. In this case, the remote computer resource 304 may perform a multiple-parameter optimization to search for an optimum combination of temperature, pressure as well as other plasma processing conditions that can minimize the non-uniformity on the first wafer after the plasma processing. Upon reaching the optimized solution, the remote computer 304 transfers the first temperature profile map and the first plasma processing conditions to the local computer 318.

Referring still to FIG. 3, a wafer stage supporting a semiconductor wafer in a plasma processing station, comprises a plurality of temperature control elements 306. Each of the plurality of temperature control elements comprises a heating element 308, a cooling element 310, and a sensing element 312 that can be individually controlled and can work all together to provide the first temperature profile map across the surface of the wafer. The temperature control circuit 314 serves to apply control signals to the heating elements 308 and cooling elements 310 responsive to the first temperature profile map provided by the remote computer resource 304 and measured temperature feedback from the sensing element 312 and temperature sensing circuit 316.

The heating elements 308 in the temperature control elements 306 can be Peltier devices and/or resistive heaters such as polyimide heaters, silicone rubber heaters, mica heaters, metal heaters (e.g. W, Ni/Cr alloy, Mo or Ta), ceramic heaters (e.g. WC), semiconductor heaters, carbon heaters, or any other suitable type of heating element as desired. The heating elements 308 in the temperature control elements 306 can be implemented in various designs or configurations, such as being screen printed, wire wound, etched foil heaters, or any other suitable design as desired.

Temperature control is further provided by cooling the wafer stage with a plurality of cooling elements 310 through the temperature control circuit 314. In some embodiments, the liquid or gaseous coolant passing through the cooling element 310 can be chilled with an external chiller (not shown) for greater cooling effect, and can be recirculated for greater efficiency. The external chiller cooling and recirculating a coolant fluid can be controlled by the temperature control circuit 314. Faster cooling rate is possible if a chiller is used to cool the coolant fluid to a temperature below atmospheric, in accordance with some embodiments. In some embodiments, the cooling elements 310 may not be necessary in the temperature control elements 306. In some embodiments, the cooling elements 310 can be shared by at least two neighbor temperature control elements 306. In some embodiments, the cooling elements 310 can be cryogenic.

Local temperature of the wafer stage is detected by the sensing element 312 through a temperature sensing circuit 316 and can be used as a feedback to the heating and cooling elements 308/310. This is particularly useful in regulating the temperature of the wafer with a desired time response. In some embodiments, different types of sensing elements can be implemented, including contact and non-contact temperature sensors depending on the desired performance, e.g., detection range, sensitivity, accuracy, response time, repeatability, size, power consumption, cost, etc. In some embodiments, a contact type temperature sensor can be a thermostat consisting two different metals (e.g., nickel, copper, tungsten, aluminum, etc.), a thermistor typically consisting ceramic materials (e.g., oxides of nickel, manganese, cobalt, etc.), a thin film resistive sensor typically consisting thin high-purity conducting metals (e.g., platinum, copper, nickel, etc.), a thermocouple consisting two different metals (e.g., copper, iron, a variety of metal alloys, etc.) and two junctions, semiconductor junctions sensors, infra-red radiation sensor and the like. In some embodiments, the heating elements can be also function as temperature sensing elements.

Temperature values at positions of each of the plurality of temperature control elements 306 is controlled by the power to the heating element 308, the temperature/flow rate of cooling fluid flowing through the fluid conduit of the cooling element 310, and the feedback from the sensing element 312, in accordance with various embodiments. Additional circuits (e.g., PID controller) or algorithm may be needed to provide an accurate heating and cooling time response, e.g., time to reach a steady-state. Accordingly, the first temperature profile map can be configured by the plurality of temperature control elements 306 for processing first wafer.

In some embodiments, the temperature control circuit 314 comprises a power supply, a coolant supply and a control circuit for each of the plurality of temperature control elements 306. In some embodiments, the temperature control circuit 314 may comprise a multiplexing control unit to regulate a plurality of heating elements 308, cooling elements 310, and sensing elements 312 with a central control which eliminates the use of individual power supply and control circuit for each of the plurality of temperature control elements 306. In some embodiments, a switch circuit can be used together with amplifiers, A/D converters, etc. in the multiplexing control unit.

The temperature control circuit 314 is a representative device and may comprise a processor, a memory, an input/output interface, a communications interface, and a system bus.

The processor may comprise any processing circuitry operative to control the operations and performance of the temperature control circuit 314 of the system 300. In various aspects, the processor may be implemented as a general purpose processor, a chip multiprocessor (CMP), a dedicated processor, an embedded processor, a digital signal processor (DSP), a network processor, an input/output (I/O) processor, a media access control (MAC) processor, a radio baseband processor, a co-processor, a microprocessor such as a complex instruction set computer (CISC) microprocessor, a reduced instruction set computing (RISC) microprocessor, and/or a very long instruction word (VLIW) microprocessor, or other processing device. The processor also may be implemented by a controller, a microcontroller, an application specific integrated circuit (ASIC), a field programmable gate array (FPGA), a programmable logic device (PLD), and so forth.

In various aspects, the processor may be arranged to run an operating system (OS) and various applications. Examples of an OS comprise, for example, operating systems generally known under the trade name of Apple OS, Microsoft Windows OS, Android OS, and any other proprietary or open source OS. Examples of applications comprise, for example, a telephone application, a camera (e.g., digital camera, video camera) application, a browser application, a multimedia player application, a gaming application, a messaging application (e.g., email, short message, multimedia), a viewer application, and so forth.

In some embodiments, at least one non-transitory computer-readable storage medium is provided having computer-executable instructions embodied thereon, wherein, when executed by at least one processor, the computer-executable instructions cause the at least one processor to perform embodiments of the methods described herein. This computer-readable storage medium can be embodied in the memory.

In some embodiments, the memory may comprise any machine-readable or computer-readable media capable of storing data, including both volatile/non-volatile memory and removable/non-removable memory. The memory may comprise at least one non-volatile memory unit. The non-volatile memory unit is capable of storing one or more software programs. The software programs may contain, for example, applications, user data, device data, and/or configuration data, or combinations therefore, to name only a few. The software programs may contain instructions executable by the various components of the control circuit 314 of the system 300.

For example, memory may comprise read-only memory (ROM), random-access memory (RAM), dynamic RAM (DRAM), Double-Data-Rate DRAM (DDR-RAM), synchronous DRAM (SDRAM), static RAM (SRAM), programmable ROM (PROM), erasable programmable ROM (EPROM), electrically erasable programmable ROM (EEPROM), flash memory (e.g., NOR or NAND flash memory), content addressable memory (CAM), polymer memory (e.g., ferroelectric polymer memory), phase-change memory (e.g., ovonic memory), ferroelectric memory, silicon-oxide-nitride-oxide-silicon (SONOS) memory, disk memory (e.g., floppy disk, hard drive, optical disk, magnetic disk), or card (e.g., magnetic card, optical card), or any other type of media suitable for storing information.

In one embodiment, the memory may contain an instruction set, in the form of a file for executing a method of generating one or more timing libraries as described herein. The instruction set may be stored in any acceptable form of machine-readable instructions, including source code or various appropriate programming languages. Some examples of programming languages that may be used to store the instruction set comprise, but are not limited to: Java, C, C++, C#, Python, Objective-C, Visual Basic, or .NET programming. In some embodiments a compiler or interpreter is comprised to convert the instruction set into machine executable code for execution by the processor.

In some embodiments, the I/O interface may comprise any suitable mechanism or component to at least enable a user to provide input to the control circuit 314 of the system 300 and the control circuit 314 to provide output to the user. For example, the I/O interface may comprise any suitable input mechanism, including but not limited to, a button, keypad, keyboard, click wheel, touch screen, or motion sensor. In some embodiments, the I/O interface may comprise a capacitive sensing mechanism, or a multi-touch capacitive sensing mechanism (e.g., a touchscreen).

In some embodiments, the I/O interface may comprise a visual peripheral output device for providing a display visible to the user. For example, the visual peripheral output device may comprise a screen such as, for example, a Liquid Crystal Display (LCD) screen, incorporated into the control circuit 314 of the system 300. As another example, the visual peripheral output device may comprise a movable display or projecting system for providing a display of content on a surface remote from the control circuit 314 of the system 300. In some embodiments, the visual peripheral output device can comprise a coder/decoder, also known as a Codec, to convert digital media data into analog signals. For example, the visual peripheral output device may comprise video Codecs, audio Codecs, or any other suitable type of Codec.

The visual peripheral output device also may comprise display drivers, circuitry for driving display drivers, or both. The visual peripheral output device may be operative to display content under the direction of the processor. For example, the visual peripheral output device may be able to play media playback information, application screens for applications implemented on the control circuit 314 of the system 300, information regarding ongoing communications operations, information regarding incoming communications requests, or device operation screens, to name only a few.

In some embodiments, the communications interface may comprise any suitable hardware, software, or combination of hardware and software that is capable of coupling the control circuit 314 of the system 300 to one or more networks and/or additional devices. The communications interface may be arranged to operate with any suitable technique for controlling information signals using a desired set of communications protocols, services or operating procedures. The communications interface may comprise the appropriate physical connectors to connect with a corresponding communications medium, whether wired or wireless.

Systems and methods of communication comprise a network, in accordance with some embodiments. In various aspects, the network may comprise local area networks (LAN) as well as wide area networks (WAN) including without limitation Internet, wired channels, wireless channels, communication devices including telephones, computers, wire, radio, optical or other electromagnetic channels, and combinations thereof, including other devices and/or components capable of/associated with communicating data. For example, the communication environments comprise in-body communications, various devices, and various modes of communications such as wireless communications, wired communications, and combinations of the same.

Wireless communication modes comprise any mode of communication between points (e.g., nodes) that utilize, at least in part, wireless technology including various protocols and combinations of protocols associated with wireless transmission, data, and devices. The points comprise, for example, wireless devices such as wireless headsets, audio and multimedia devices and equipment, such as audio players and multimedia players, telephones, including mobile telephones and cordless telephones, and computers and computer-related devices and components, such as printers, network-connected machinery such as a circuit generating system 404, and/or any other suitable device or third-party device.

Wired communication modes comprise any mode of communication between points that utilize wired technology including various protocols and combinations of protocols associated with wired transmission, data, and devices. The points comprise, for example, devices such as audio and multimedia devices and equipment, such as audio players and multimedia players, telephones, including mobile telephones and cordless telephones, and computers and computer-related devices and components, such as printers, network-connected machinery, and/or any other suitable device or third-party device. In various implementations, the wired communication modules may communicate in accordance with a number of wired protocols. Examples of wired protocols may comprise Universal Serial Bus (USB) communication, RS-232, RS-422, RS-423, RS-485 serial protocols, FireWire, Ethernet, Fiber Channel, MIDI, ATA, Serial ATA, PCI Express, T-1 (and variants), Industry Standard Architecture (ISA) parallel communication, Small Computer System Interface (SCSI) communication, or Peripheral Component Interconnect (PCI) communication, to name only a few examples.

Accordingly, in various aspects, the communications interface may comprise one or more interfaces such as, for example, a wireless communications interface, a wired communications interface, a network interface, a transmit interface, a receive interface, a media interface, a system interface, a component interface, a switching interface, a chip interface, a controller, and so forth. When implemented by a wireless device or within wireless system, for example, the communications interface may comprise a wireless interface comprising one or more antennas, transmitters, receivers, transceivers, amplifiers, filters, control logic, and so forth.

In various embodiments, the communications interface may provide voice and/or data communications functionality in accordance a number of wireless protocols. Examples of wireless protocols may comprise various wireless local area network (WLAN) protocols, including the Institute of Electrical and Electronics Engineers (IEEE) 802.xx series of protocols, such as IEEE 802.11a/b/g/n, IEEE 802.16, IEEE 802.20, and so forth. Other examples of wireless protocols may comprise various wireless wide area network (WWAN) protocols, such as GSM cellular radiotelephone system protocols with GPRS, CDMA cellular radiotelephone communication systems with 1×RTT, EDGE systems, EV-DO systems, EV-DV systems, HSDPA systems, and so forth. Further examples of wireless protocols may comprise wireless personal area network (PAN) protocols, such as an Infrared protocol, a protocol from the Bluetooth Special Interest Group (SIG) series of protocols, including Bluetooth Specification versions v1.0, v1.1, v1.2, v2.0, v2.0 with Enhanced Data Rate (EDR), as well as one or more Bluetooth Profiles, and so forth. Yet another example of wireless protocols may comprise near-field communication techniques and protocols, such as electromagnetic induction (EMI) techniques. An example of EMI techniques may comprise passive or active radio-frequency identification (RFID) protocols and devices. Other suitable protocols may comprise Ultra Wide Band (UWB), Digital Office (DO), Digital Home, Trusted Platform Module (TPM), ZigBee, and so forth.

In some embodiments, the control circuit 314 of the system 300 may comprise a system bus that couples various system components including the processor, the memory, and the I/O interface. The system bus can be any of several types of bus structure(s) including a memory bus or memory controller, a peripheral bus or external bus, and/or a local bus using any variety of available bus architectures including, but not limited to, 9-bit bus, Industrial Standard Architecture (ISA), Micro-Channel Architecture (MCA), Extended ISA (EISA), Intelligent Drive Electronics (IDE), VESA Local Bus (VLB), Personal Computer Memory Card International Association (PCMCIA) Bus, Small Computer System Interface (SCSI) or other proprietary bus, or any custom bus suitable for computing device applications.

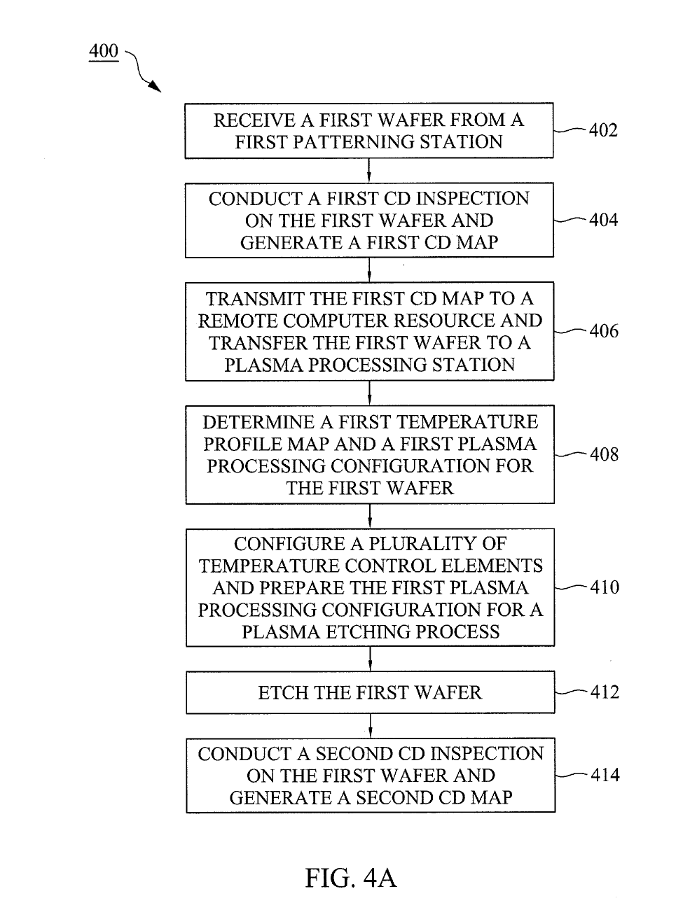

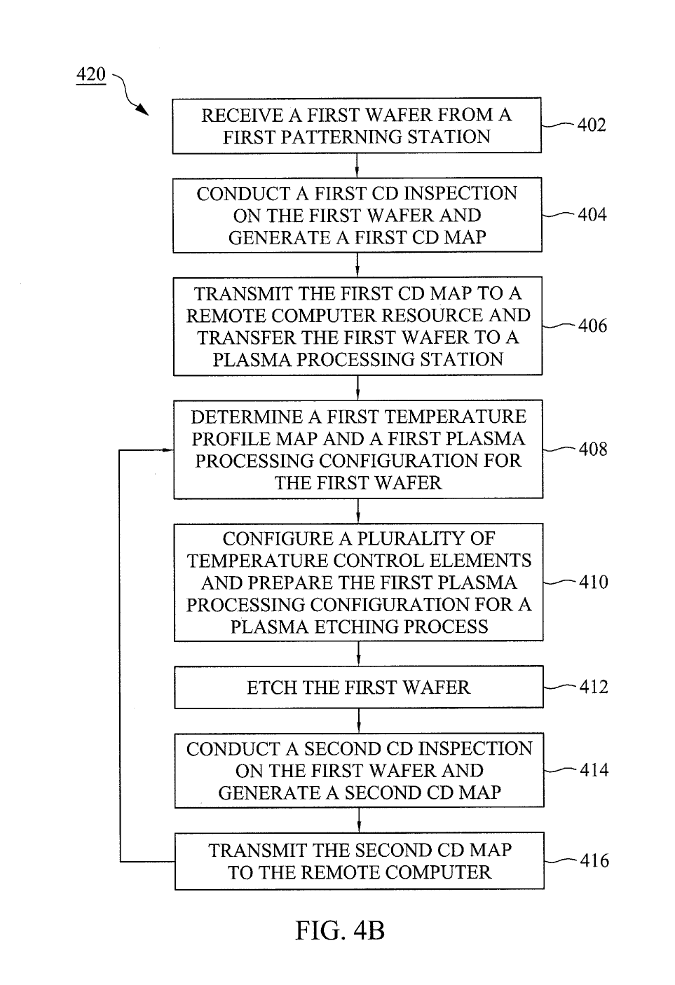

FIG. 4A illustrates a flowchart of an in-line processing control method 400, in accordance with various embodiments of the present disclosure. The method 400 starts with operation 402, wherein a first wafer with at least one pattern from a first patterning process (e.g., photolithography) is received by an in-line CD inspection station.

The method 400 continues with operation 404, a first CD inspection (e.g., ADI-CD inspection) is conducted in the in-line CD inspection station and a first CD map of the first wafer is generated. The first CD map of the first wafer may be generated using a CD-SEM by obtaining a plurality of electron microscopic images from a plurality of test positions on the first wafer and by measuring a plurality of critical dimension values of the at least one pattern in the plurality of electron microscopic images. The number of test positions may be specified by the user. The first CD map can provide accurate position-dependent critical dimension values on the first wafer after the first patterning process (e.g., photolithography). In some embodiments, the in-line CD inspection station can be an optical inspection tool according to the size of the features.

The process 400 continues with operation 406 wherein the first CD map created by the in-line CD inspection station is transmitted to a remote computer resource and the first wafer is transferred from the in-line CD inspection station to a plasma processing station.

The process 400 continues with operation 408, wherein the first CD map is further analyzed by the remote computer resource to configure a first temperature profile map and a first plasma processing configuration. The first plasma processing configuration can comprise a plurality of configuration parameters for the plasma processing station, including a first etch time and a first plasma processing condition, wherein the first plasma processing condition may comprise a first pressure, a first pressure distribution, a first plasma power, a first time response of the temperature, etc.

The process 400 continues with operation 410, wherein the first temperature profile map and the first plasma processing configuration are transmitted from the remote computer resource to a local computer associated with the plasma processing station. The local computer can receive the first temperature profile map from the remote computer over a wired or wireless network connection, in some embodiments. The critical device parameters can be also transmitted to the local computer, in certain embodiments. Based on the first temperature profile map of the first wafer, the local computer can independently configure each of the plurality of temperature control elements on the wafer stage holding the first wafer through the temperature control circuit to a specified temperature value. In operation 410, the local computer also configures the plasma processing chamber according to the first plasma processing configuration, including etch time, pressure, pressure distribution, plasma power, time response of the temperature, etc.

The process 400 continues with operation 412 and 414, wherein the first wafer is etched in the plasma processing station and inspected again in the CD inspection station, wherein a second CD map can be obtained. The first wafer is then ready to be transmitted to a next processing station or a storage station, according to certain embodiments. The second wafer from the first patterning process can be then loaded to the CD inspection station.

When a second wafer is to be processed in the plasma etching system, and the second wafer may have a different third CD map of the second wafer from the first CD map of the first wafer, based on an exemplary method described herein the remote computer resource determines a second temperature profile map and a second plasma processing configuration to achieve the desired uniformity in a fourth CD map on the second wafer after the plasma etching process. The local computer further configures the plurality of temperature control elements to provide a second temperature profile map and prepares the plasma processing chamber for etching the second wafer according to the second plasma processing configuration.

In some embodiments, a first CD map can be replaced by a first thickness map of a wafer from a first process measured using techniques, such as for instance reflectance spectrometer, spectroscopic ellipsometer, etc., in accordance with some embodiments. Similarly, the thickness map can be used as a feedforward to the plurality of temperature control elements in a second process, such as but not limited to plasma enhanced chemical vapor deposition, and plasma enhanced atomic layer deposition. Similar to the etching rate, the growth rate can be also locally adjusted by a temperature profile map generated according to the first thickness map so that the non-uniformity in a second thickness map of the wafer after the second process can be compensated. In some embodiments, a thickness map can be also used as a feedforward to a chemical mechanical planarization (CMP) process to configure a plurality of temperature control elements.

FIG. 4B illustrates a flowchart of an in-line processing control method 420, in accordance with various embodiments of the present disclosure. Operations 402-414 are the same as the operations in process 400. The process 420 continues with operation 414, wherein a second CD inspection is conducted and a second CD map of the first wafer is generated. The second CD map of the first wafer may be generated by the same in-line CD inspection station as the one used for obtaining the first CD map. In some embodiments, the plurality of test positions in operation 414 are the same as the one used in the first CD inspection.

The process 420 continues with operation 416 and 408, wherein the second CD map at the plurality of test positions on the first wafer created by the in-line CD inspection station is transmitted to and analyzed by a remote computer resource, wherein the remote computer resource determines a second temperature profile map and the second plasma processing configuration based on the first and the second CD maps.

In some embodiments, both the first and the second CD maps of wafers from different plasma processing stations can be stored in a database, for example in the remote computer resource. Data mining and data analysis techniques can be used to systematically explore the differences in temperature control and plasma processing behaviors of the different plasma processing stations. The unique temperature control and plasma processing behavior associated with each plasma processing station can be also studied by machine learning and eventually considered for determining the temperature profile map and the plasma processing configurations when different plasma processing stations are used.

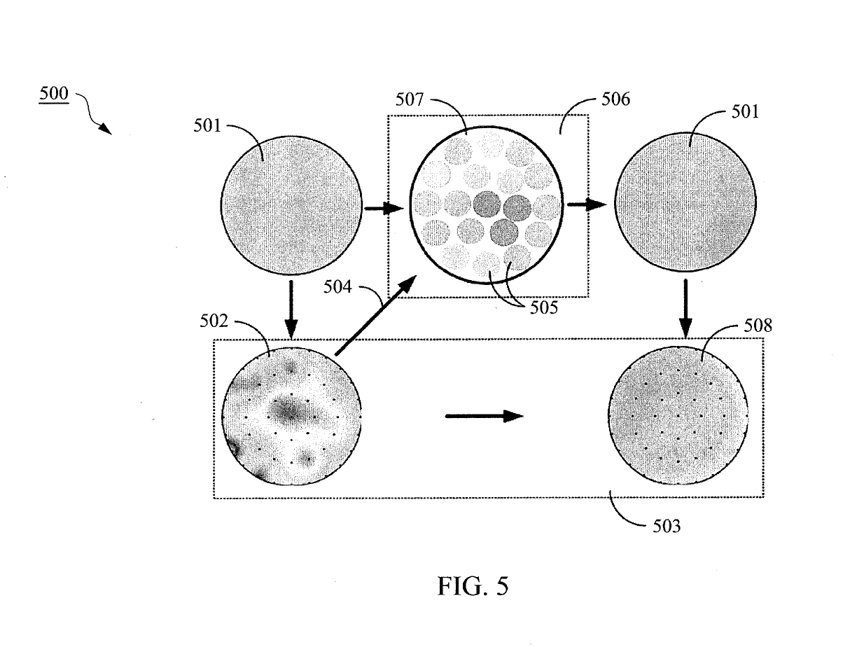

FIG. 5 illustrates exemplary data 500 showing an improved critical dimension uniformity using the present in-line processing control method and system, in accordance with various embodiments of the present disclosure. It is noted that the exemplary data 500 and the operation thereof is merely an example, and is not intended to limit the present disclosure. Accordingly, it is understood that additional operations may be provided before, during, and after the operations, and that some other operations may only be briefly described herein.

A first CD map (e.g., ADI-CD map) 502 on a wafer 501 is obtained by inspecting the wafer surface in a CD inspection station 503. It can be seen that the critical dimension distribution has a non-uniformity across the entire wafer surface, where the CD values are higher at the center of the surface of the wafer 501. The wafer 501 is then transferred on to a wafer stage in a plasma processing station 506 with a plurality of temperature control elements 505 for a plasma etching process. The temperature setting on each of the temperature control element 505 on the surface of the wafer stage is configured by a first temperature profile map 507. The first temperature profile map 507 together with a first plasma processing configuration is determined based on the first CD map 502. The temperature profile map 507 is used to adjust local temperatures on the surface of the wafer 501 and thus etching rates. A second CD map 508 on the wafer 501 after the plasma etching process can be obtained using the CD inspection station. Compared to the first CD map 502, the second CD map 508 shows a rather uniform CD values across the entire surface of the wafer 501. Accordingly, the non-uniformity in the first CD map 502 can be compensated by creating the first temperature profile map 507 on the wafer 501 during the plasma etching process.

In an embodiment, an in-line processing control method comprising: conducting a critical dimension (CD) inspection on a first wafer; generating a first CD map of the first wafer; determining a first temperature profile map and a first plasma processing configuration based on the first CD map of the first wafer, wherein the first plasma processing configuration comprises a first temperature profile map, a first etch time and a first plasma processing condition; and configuring a plasma etching process with the first plasma processing configuration for processing the first wafer.

In another embodiment, an in-line processing control system comprising: a patterning processing station; an in-line critical-dimension (CD) inspection station, wherein the in-line CD inspection station is configured to automatically collect at least one CD value of at least one pattern on a first wafer to create a first CD map; and a plasma processing station, wherein the plasma processing station comprises a plurality of temperature control elements on a wafer stage, wherein the plurality of temperature control elements is configured based on the first CD map.

Yet in another embodiment, An in-line processing control comprising: a first processing station, wherein the first processing station is configured to produce at least one feature on a semiconductor wafer; an inspection station, wherein the inspection station is configured to generate a first critical dimension (CD) map of the at least one feature on the semiconductor wafer; and a second processing station, wherein the second processing station is configured to provide a second processing on the semiconductor wafer and comprises a plurality of temperature control elements on a wafer stage.

Although the disclosure has been described in terms of exemplary embodiments, it is not limited thereto. Rather, the appended claims should be construed broadly, to include other variants and embodiments of the disclosure, which may be made by those of ordinary skill in the art without departing from the scope and range of equivalents of the disclosure.

What is claimed is:

1. An in-line processing control method comprising:
conducting a critical dimension (CD) inspection on a first wafer;
generating a first CD map of the first wafer;
determining a first temperature profile map and a first plasma processing configuration based on the first CD map of the first wafer, wherein the first plasma processing configuration comprises a first temperature profile map, a first etch time and a first plasma processing condition; and
configuring a plasma etching process with the first plasma processing configuration for processing the first wafer.

2. The method of claim 1, wherein the first CD map is generated by a CD scanning electron microscope (CD-SEM).

3. The method of claim 1, wherein the first plasma processing configuration is determined to minimize a non-uniformity in a second CD map of the first wafer after the plasma etching process is performed on the first wafer.

4. The method of claim 1, wherein the first temperature profile map is used to configure a plurality of temperature control elements on a wafer stage holding the first wafer during the plasma etching process.

5. The method of claim 4, wherein each of the plurality of temperature control elements comprises at least one of: a heating element, a cooling element and a sensing element.

6. The method of claim 1, wherein the first plasma processing condition comprises at least one of: a plasma power, a pressure, a pressure distribution and a temperature ramping profile.

7. The method of claim 1, further comprising:
receiving the first wafer from a first patterning process;
transmitting the first CD map to a remote computer resource;
generating a second temperature profile map and a second plasma processing configuration for processing a second wafer based on a third CD map;
wherein the second temperature profile map for the second wafer is different from the first temperature profile map for the first wafer in response to differences between the first and the third CD maps, wherein the second plasma processing configuration comprises a second etch time and a second plasma processing condition.

8. An in-line processing control system comprising:
a patterning processing station;
an in-line critical-dimension (CD) inspection station, wherein the in-line CD inspection station is configured to automatically collect at least one CD value of at least one pattern on a first wafer to create a first CD map; and
a plasma processing station, wherein the plasma processing station comprises a plurality of temperature control elements on a wafer stage, wherein the plurality of temperature control elements is configured based on the first CD map.

9. The system of claim 8, wherein the patterning processing station is configured to create the at least one pattern on the first wafer;

10. The system of claim 8, wherein the patterning processing station is configured to conduct at least one step in a photolithography process.

11. The system of claim 8 further comprises a remote computer resource, wherein the remote computer resource is configured to
receive the first CD map of the first wafer from the in-line CD inspection station;
generate a first temperature profile map and a first plasma processing configuration based on the first CD map for processing the first wafer in the plasma processing station; and
transmit the first temperature profile map and the first plasma processing configuration to the plasma processing station.

12. The system of claim 11, wherein the first plasma processing configuration
minimizes a non-uniformity in a second CD map wherein the second CD map is determined on the first wafer after a plasma etching process, and
comprises a first etch time and a first plasma processing condition.

13. The system of claim 8, wherein the plasma processing station is configured to perform the plasma etching process on the first wafer according to the first plasma processing configuration.

14. The system of claim 8, wherein the plurality of temperature control elements can be individually configured to produce the first temperature profile map on the wafer stage holding the first wafer during the plasma etching process.

15. The system of claim 8, wherein each of the plurality of temperature control elements comprises at least one of: a heating element, a cooling element and a sensing element.

16. An in-line processing control comprising:
a first processing station, wherein the first processing station is configured to produce at least one feature on a semiconductor wafer;
an inspection station, wherein the inspection station is configured to generate a first critical dimension (CD) map of the at least one feature on the semiconductor wafer; and
a second processing station, wherein the second processing station is configured to provide a second processing on the semiconductor wafer and comprises a plurality of temperature control elements on a wafer stage.

17. The system of claim 16, wherein the first CD map is generated by a CD scanning electron microscope (CD-SEM).

18. The system of claim 16, wherein the inspection station is configured to generate a second CD map after the second processing.

19. The system of claim 16 further comprises a remote computer, wherein the remote computer is configured to
generates a first temperature profile based on the first CD map;
receive the second CD map from the inspection station;
generate a second temperature profile map and a second plasma processing configuration based on the first and second CD maps; and
transmit the second temperature profile map and the second plasma processing configuration to the second processing station, wherein the second temperature profile map is used to configure the plurality of temperature control elements on the wafer stage holding the semiconductor wafer during the second processing.

20. The system of claim 16, wherein the plurality of temperature control elements can be individually configured to produce the first and second temperature profile maps on a wafer stage.

21. The system of claim 16, wherein each of the plurality of temperature control elements comprises a heating element and a sensing element.
